(19) United States
(12) Patent Application Publication
(10) Pub. No.: US 2022/0108872 A1
(43) Pub. Date: Apr. 7, 2022

(54) BEVEL BACKSIDE DEPOSITION ELIMINATION

(71) Applicant: Applied Materials, Inc., Santa Clara, CA (US)

(72) Inventors: Zubin Huang, Santa Clara, CA (US); Diwakar Kedlaya, San Jose, CA (US); Rui Cheng, San Jose, CA (US); Truong Van Nguyen, Milpitas, CA (US); Manjunath Patil, Bengaluru (IN); Pavan Kumar Murali Kumar, Bangalore (IN); Subrahmanyam Veerisetty, Bangalore (IN); Karthik Janakiraman, San Jose, CA (US)

(73) Assignee: Applied Materials, Inc., Santa Clara, CA (US)

(21) Appl. No.: 17/063,366

(22) Filed: Oct. 5, 2020

(51) Int. Cl. H01J 37/32; C23C 16/44; C23C 16/50; C23C 16/56

(52) U.S. Cl. CPC H01J 37/3244; H01J 37/32715; H01J 37/32357; H01J 2237/332; C23C 16/4408; C23C 16/50; C23C 16/56; H01J 37/32642

(57) ABSTRACT

Exemplary semiconductor processing systems may include a chamber body comprising sidewalls and a base. The systems may include a substrate support extending through the base of the chamber body. The substrate support may include a support plate defining a plurality of channels through an interior of the support plate. Each channel of the plurality of channels may include a radial portion extending outward from a central channel through the support plate. Each channel may also include a vertical portion formed at an exterior region of the support plate fluidly coupling the radial portion with a support surface of the support plate. The substrate support may include a shaft coupled with the support plate. The central channel may extend through the shaft. The systems may include a fluid source coupled with the central channel of the substrate support.

### TECHNICAL FIELD

The present technology relates to components and apparatuses for semiconductor manufacturing. More specifically, the present technology relates to processing chamber components and other semiconductor processing equipment and methods.

### BACKGROUND

Integrated circuits are made possible by processes which produce intricately patterned material layers on substrate surfaces. Producing patterned material on a substrate requires controlled methods for forming and removing material. Precursors are often delivered to a processing region and distributed to uniformly deposit or etch material on the substrate. Many aspects of a processing chamber may impact process uniformity, such as uniformity of process conditions within a chamber, uniformity of flow through components, as well as other process and component parameters. Even minor discrepancies across a substrate may impact the formation or removal process. Additionally, the components within the chamber may impact deposition on chamber components or edge and backside regions of a substrate.

Thus, there is a need for improved systems and methods that can be used to produce high quality devices and structures. These and other needs are addressed by the present technology.

### SUMMARY

Exemplary semiconductor processing systems may include a chamber body comprising sidewalls and a base. The systems may include a substrate support extending through the base of the chamber body. The substrate support may include a support plate defining a plurality of channels through an interior of the support plate. Each channel of the plurality of channels may include a radial portion extending outward from a central channel through the support plate. Each channel may also include a vertical portion formed at an exterior region of the support plate fluidly coupling the radial portion with a support surface of the support plate. The substrate support may include a shaft coupled with the support plate. The central channel may extend through the shaft. The systems may include a fluid source coupled with the central channel of the substrate support.

In some embodiments, the fluid source may include a hydrogen-containing precursor or a halogen-containing precursor. The systems may include a remote plasma source unit coupled with the fluid source. The remote plasma source unit may be configured to deliver radical species through the central channel of the substrate support. The central channel may include a corrosion resistant material extending through the shaft of the substrate support. The support plate may define a recessed ledge formed at a radius to create an amount of overhang of a substrate about the support plate. The systems may include an edge ring seated on an exterior portion of the support plate. The edge ring may be positioned radially outward of the vertical portion of each channel of the plurality of channels. The edge ring may extend over the vertical portion of each channel to form a fluid path extending over the recessed ledge of the support plate. The systems may include a shadow ring seated on the edge ring. The shadow ring may extend radially inward over a portion of the support plate and form a fluid path from the plurality of channels defined in the support plate to a substrate support region of the support plate.

Some embodiments of the present technology may encompass semiconductor processing systems. The systems may include a chamber body including sidewalls and a base. The systems may include a substrate support extending through the base of the chamber body. The substrate support may include a support plate defining a plurality of channels through an interior of the support plate. Each channel of the plurality of channels may include a radial portion extending outward from a central channel through the support plate. Each channel may include a vertical portion formed at an exterior region of the support plate fluidly coupling the radial portion with a support surface of the support plate. The support plate may define a fluid path along a support region of the support plate. The substrate support may include a shaft coupled with the support plate. The central channel may extend through the shaft. The systems may include a fluid pump coupled with the central channel of the substrate support.

In some embodiments, the systems may include a purge channel coupled with the fluid path, and configured to deliver a purge gas along the fluid path. The support plate may define a recessed ledge formed at a radius to create an amount of overhang of a substrate about the support plate. The systems may include an edge ring seated on an exterior portion of the support plate. The edge ring may be positioned radially outward of the vertical portion of each channel of the plurality of channels. The edge ring may extend over the vertical portion of each channel to form a fluid path extending over the recessed ledge of the support plate.

Some embodiments of the present technology may encompass methods of semiconductor processing. The methods may include forming a plasma of a deposition precursor in a processing region of a semiconductor processing chamber. The methods may include depositing material on a substrate seated on a substrate support. The methods may include flowing a purge fluid through a plurality of channels formed in the substrate support. The purge fluid may limit or remove deposition material from an edge of the substrate.

In some embodiments, flowing the purge fluid may include forming plasma effluents of a purge gas. Flowing the purge fluid may include flowing the plasma effluents through the plurality of channels formed in the substrate support. The plasma effluents may be flowed subsequent the depositing. The plasma effluents may be flowed during the depositing. The substrate support may be a support plate defining a plurality of channels through an interior of the support plate. Each channel of the plurality of channels may include a radial portion extending outward from a central channel through the support plate. Each channel may include a vertical portion formed at an exterior region of the support plate fluidly coupling the radial portion with a support surface of the support plate. The substrate support may include a shaft coupled with the support plate, wherein the central channel extends through the shaft. The support plate may define a recessed ledge formed at a radius to create an amount of overhang of a substrate about the support plate. The substrate support may include an edge ring seated on an exterior portion of the support plate. The edge ring may be positioned radially outward of the vertical portion of each channel of the plurality of channels.

Such technology may provide numerous benefits over conventional systems and techniques. For example, embodiments of the present technology may remove substrate backside deposition while limiting backside damage to the substrate. Additionally, some embodiments of the present technology may limit or prevent deposition on a backside or edge region of a substrate being processed. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic cross-sectional view of an exemplary processing chamber according to some embodiments of the present technology.

FIG. 4 shows operations of an exemplary method of semiconductor processing according to some embodiments of the present technology.

FIG. 5 shows a schematic cross-sectional view of an exemplary processing chamber according to some embodiments of the present technology.

FIG. 6 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced chemical vapor deposition and thermal chemical vapor deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. Additionally, other dielectric materials may be deposited to separate transistors on a substrate, or otherwise form semiconductor structures. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

While lid stack components may beneficially distribute precursors into a processing region to facilitate uniform deposition, structures and operations to ensure more uniform coverage across the substrate may extend deposition past a patterned region of the substrate, and onto edge regions. Based on flow properties within the chamber processing region, deposition may also extend to the backside of the substrate. If allowed to remain on the substrate, the material deposited on the backside may fall to other substrates during transfer, or impact downstream processing. To address this issue, conventional technologies may be forced to perform a subsequent wet etch after deposition. However, such a process may have multiple drawbacks. For example, performing an additional etch process subsequent the deposition may increase queue times, reducing throughput for the system. Additionally, selectivity between the film deposited and the underlying substrate may not be very high, which may create substantial damage to the underlying substrate.

The present technology overcomes these challenges by utilizing incorporated channels and a distribution path through the substrate support. The channels may be used to deliver a variety of materials that may limit or remove deposition products that may otherwise be deposited on the edges or backside of the substrate. Accordingly, the present technology may afford improved deposition processes, which may reduce queue times and better protect substrates from additional etch or backside damage.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

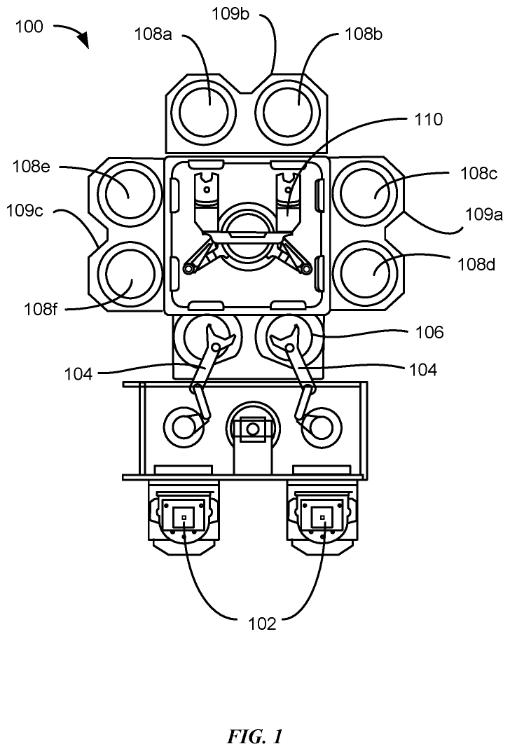

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

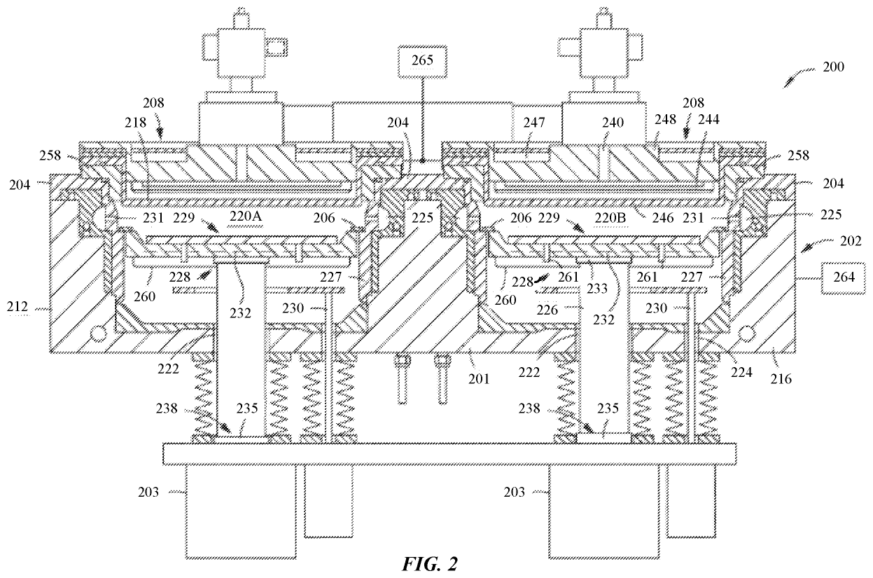

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

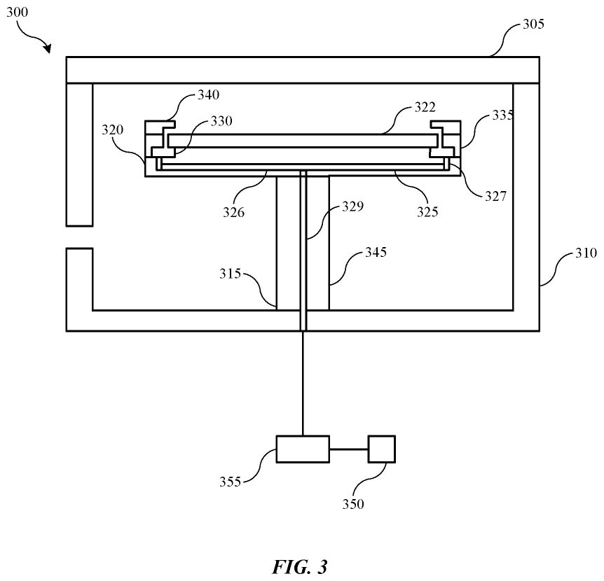

FIG. 3 shows a schematic partial cross-sectional view of an exemplary processing system 300 according to some embodiments of the present technology. FIG. 3 may illustrate further details relating to components in system 200, such as for pedestal 228. System 300 is understood to include any feature or aspect of system 200 discussed previously in some embodiments. The system 300 may be used to perform semiconductor processing operations including deposition of hardmask materials or other materials as previously described, as well as other deposition, removal, or cleaning operations. System 300 may show a partial view of the chamber components being discussed and that may be incorporated in a semiconductor processing system, and may illustrate a view without several of the lid stack components noted above. Any aspect of system 300 may also be incorporated with other processing chambers or systems as will be readily understood by the skilled artisan.

System 300 may include a processing chamber including a faceplate 305, through which precursors may be delivered for processing, and which may be coupled with a power source for generating a plasma within the processing region of the chamber. The chamber may also include a chamber body 310, which as illustrated may include sidewalls and a base. A pedestal or substrate support 315 may extend through the base of the chamber as previously discussed. The substrate support may include a support plate 320, which may support semiconductor substrate 322. The support plate 320 may define a number of features, which may facilitate processing operations as will be discussed further below. For example, support plate 320 may define a plurality of channels 325 extending through an interior portion of the support plate 320. Any number of channels 325 may be included within the support plate, and may extend radially outward from central channel 329 extending into the support plate. From central channel 329, each channel 325 may include a radial portion 326 providing fluid access from the central channel 329 to an exterior portion of the support plate 320. Each channel 325 may transition from the radial portion 326 to a vertical portion 327, which may be formed at an exterior region of the support plate 320. Vertical portion 327 may fluidly couple each radial portion with a surface of the support plate, such as a surface on which substrate 322 may be seated. The portions may form a number of fluid paths extending from central channel 329 to a number of locations at an exterior region of the support plate, such as a region radially outward of the substrate support surface.

The channels 325 may be formed at regular intervals from one another and may all extend an equal amount through the support plate, or may extend to different radial locations. As noted, any number of channels 325 may be included, and some embodiments of the present technology may include greater than or about 2 channels, and may include greater than or about 4 channels, greater than or about 4 channels, greater than or about 4 channels, greater than or about 4 channels, greater than or about 4 channels, greater than or about 4 channels, greater than or about 4 channels, greater than or about 4 channels, greater than or about 4 channels, or more. The number of channels may impact a uniformity of distribution as will be described further below, and more channels may improve uniformity of fluid delivery or removal. However, increasing channels may impact a uniformity of heat distribution through the support plate by removing more material to form channels. Accordingly, in some embodiments support plates may include less than or about 20 channels, less than or about 18 channels, less than or about 16 channels, or less.

Support plate 320 may define a recessed ledge 330 formed at an exterior location of the support plate. The recessed ledge 330 may be formed at any radial location, and in some embodiments may be formed radially inward of the vertical portions 327 of the channels 325. In some embodiments the recessed ledge 330 may also be formed radially inward of an exterior edge of a substrate to be processed in the chamber, such as substrate 322 as illustrated. For example, recessed ledge 330 may be formed at a radius of the support plate 320 to create an amount of overhang of substrate 322 when seated on support plate 320. Accordingly, a support surface of the support plate may extend less than an outer radial dimension of a substrate to be processed. This may provide access to the backside of the substrate as illustrated. In some embodiments, substrate support 315 may be an electrostatic chuck including one or more incorporated electrodes or a vacuum chuck including one or more vacuum chuck ports, which may ensure a substrate remains chucked during processing operations as will be described further below.

An edge ring 335 may be seated at an exterior location on the support plate 320 in some embodiments. Edge ring 335 may be located at any location, and may be positioned at a location radially outward of vertical portion 327 of channels 325. Additionally, as illustrated, in some embodiments the edge ring may be seated at a radial or exterior edge of support plate 320. Edge ring 335 may include a vertical portion and a portion extending radially inward along the support plate towards a substrate location. As illustrated, the portion of the edge ring extending inward may extend to or towards the vertical portion 327 of the channels 325. Additionally, in some embodiments as illustrated, edge ring 335 may extend over or radially inward past the vertical portion 327 of each channel 325. This may form a fluid path where fluid flowed or drawn through channels 325 may extend over the recessed ledge 330 of the support plate along the path defined at least partially by the edge ring. Edge ring 335 may extend to any vertical height off a surface of the support plate, and may extend up to, level with, or beyond a height of a substrate 322 or substrate support surface of support plate 320. This may allow a fluid flowed through channels 325 to extend across a backside and edge region of a substrate being processed, which may limit or prevent deposition along these regions of the substrate. Additionally, as will be discussed further below, an etch process may be performed to remove material that may be deposited on the edge or backside regions during processing in some embodiments.

In some embodiments, processing system 300 may also include a shadow ring 340 which may be seated on or extend over edge ring 335. Shadow ring 340 may be connected with the edge ring during processing. For example, the substrate support may be raised to a processing location, and may contact and accept shadow ring 340 in some embodiments. Shadow ring 340 may extend radially inward of an internal edge of edge ring 335. Shadow ring 340 may extend radially inward over a portion of support plate 320, and may extend over an exterior edge of where a substrate 322 may be seated on substrate support 315. Accordingly, shadow ring 340 may extend the fluid path formed by edge ring 335, for example, and may form a fluid path from the plurality of channels 325 defined in the support plate 320 that may extend into a substrate support region of the support plate as illustrated. This may allow a fluid delivered through the fluid channels to block or dilute deposition material formed in the plasma or thermal processing region, and may limit or prevent deposition on edge regions of the substrate.

The support plate 320 may be coupled with a shaft 345, which may extend through the base of the chamber. Shaft 345 may provide access for a number of fluid and electrical connections, including central channel 329. Central channel 329 may at least partially extend through support plate 320 and through shaft 345 providing fluid access to the channels 325 formed within the substrate support. Central channel 329 may be fluidly coupled with a fluid source 350, which may provide one or more materials to the central channel 329, and through channels 325 to flow through the fluid paths defined by the edge ring 335. An optional remote plasma source 355 may be incorporated, which may allow materials from fluid source 350 to be plasma enhanced prior to delivery into the channels through the substrate support. For example, fluid source 350 may provide any number of materials including a noble gas, a hydrogen-containing fluid such as hydrogen, a halogen-containing precursor including nitrogen trifluoride or any other fluorine-containing or chlorine-containing precursor, an oxygen-containing fluid such as oxygen, among any other materials that may be flowed through the central channel an channels 325 to provide an edge and backside effect on processing conditions.

When remote plasma source 355 may be included in the system 300, the unit may receive any material from fluid source 350 and then provide plasma enhanced effluents of that material through the central channel 329 of the substrate support. Because in some embodiments the material flowed through the remote plasma unit may be corrosive, such as a halogen-containing material, in some embodiments central channel 329 may be formed from or contained in a corrosion-resistant material, such as stainless steel or an oxidized material, or any other material that may prevent corrosion from the radical species. Additionally, central channel 329 may be fluidly isolated from any other channel extending within the shaft 345, and may be fluidly isolated from the remote plasma unit 355 to the channels 325 within the support plate of the substrate support.

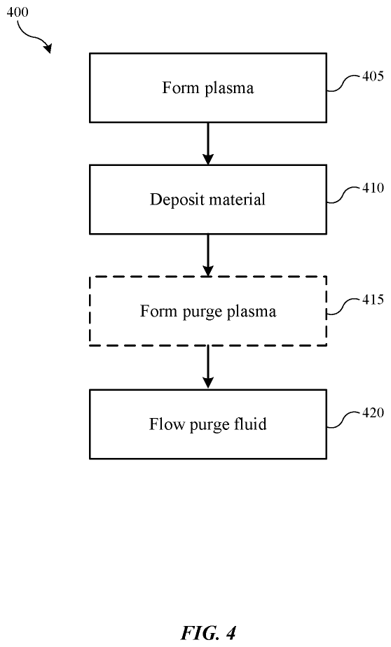

As explained previously, the present technology may provide remedial or preventive operations to limit or prevent backside and edge deposition on substrates. FIG. 4 shows operations of an exemplary method 400 of semiconductor processing according to some embodiments of the present technology. The method may be performed in a variety of processing chambers, including processing systems 200 and 300 described above, which may include substrate supports having channels, edge rings, shadow rings, fluid sources, or remote plasma systems in embodiments of the present technology. Method 400 may include a number of optional operations, which may or may not be specifically associated with some embodiments of methods according to the present technology. For example, many of the operations are described in order to provide a broader scope of the technology, but are not critical to the technology, or may be performed by alternative methodology as would be readily appreciated.

Method 400 may include additional operations prior to initiation of the listed operations. For example, semiconductor processing may be performed prior to initiating method 400. Processing operations may be performed in the chamber or system in which method 400 may be performed, or processing may be performed in one or more other processing chambers prior to delivering the component into the cleaning system in which method 400 may be performed. Once a substrate has been received in a processing chamber, such as including some or all of components from system 300 described above, method 400 may include forming a plasma of one or more deposition precursors in a processing region of a semiconductor processing chamber at operation 405. The substrate may be positioned on a substrate support, such as support 315 described above, which may include any component, feature, or characteristic described above. From the plasma effluents of the one or more deposition precursors, a material may be deposited on the substrate at operation 410. While conventional technologies may additionally deposit materials on edge regions and a backside of the substrate, the present technology may utilize one or more purge fluids to limit or remove deposition on edge and backside regions.

For example, in some embodiments, an inert material such as helium, nitrogen, argon, or a hydrogen-containing precursor, such as hydrogen, may be flowed through the channels in the substrate support at operation 420, which may flow about the edge regions of the substrate, and when a shadow ring is included, may also flow over an edge region of the substrate. In some deposition processes for silicon-containing or carbon-containing films, hydrogen gas may be a byproduct of the deposition process. When additional hydrogen is flowed across edge regions on the backside and/or front side of the substrate, a dilution effect may occur by increasing the deposition byproduct concentration in these regions, which may suppress or prevent deposition. The hydrogen may be co-flowed during the deposition process, such as during operations 405 and 510, for example.

Additionally, in some embodiments a hydrogen-containing precursor, such as hydrogen, may be flowed into a remote plasma source as previously described, which may form plasma effluents of the purge fluid at optional operation 415. The plasma effluents may be flowed through central channel 329 and channels 325 to flow about the edge region of the substrate along a fluid path formed partially by an edge ring and/or shadow ring at operation 420. The plasma effluents may further dilute the deposition materials when flowed during the depositing, and may react with deposition precursors to increase byproduct production at edge regions, which may limit or prevent deposition.

In some embodiments a halogen-containing precursor may be flowed to perform an etch process subsequent the deposition. For example, the deposition process may deposit an amount of material on an edge region and/or a backside of the substrate. Once the deposition has been completed, a halogen-containing precursor may be flowed into a remote plasma source fluidly coupled with the central channel through the substrate support. A plasma may be generated and plasma effluents may be flowed through the central channel and channels, such as channels 325, which may perform an etch process on the edge region and/or backside of the substrate. Unlike conventional processes, which may transfer the substrate to a separate chamber and perform a wet etch process, the present technology may perform the etch subsequent the deposition in the same chamber, and may limit the etch process to an exterior region of the substrate, which may reduce or limit etch material contact with the backside of the wafer.

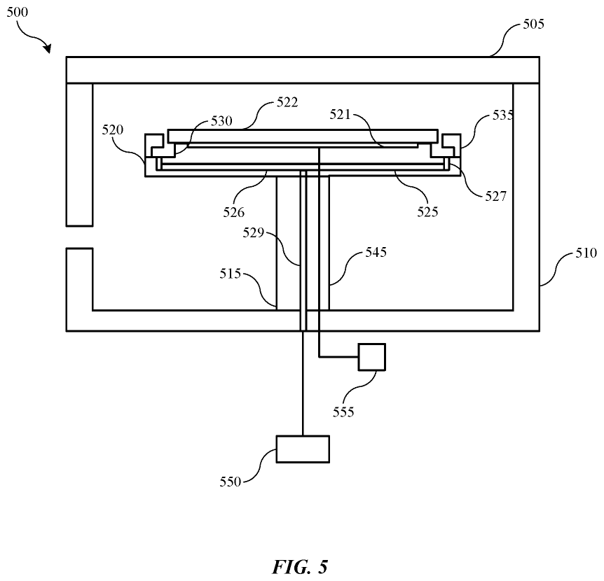

FIG. 5 shows a schematic partial bottom plan view of a processing system 500 according to some embodiments of the present technology. FIG. 5 may include one or more components discussed above with regard to FIG. 2 or 3, and may include any component, feature, or characteristic of any component discussed above, and may illustrate further details relating to any of those chambers. For example, system 500 may include a processing chamber including a faceplate 505, a chamber body 510, and a pedestal or substrate support 515 as previously described. The substrate support may include a support plate 520, which may support semiconductor substrate 522. The support plate 520 may define a number of features, which may facilitate processing operations as will be discussed further below, including an interior flow path 521 beneath an interior region where substrate 522 may be supported. Additionally, support plate 320 may define a plurality of channels 525 extending radially outward from central channel 529 extending into the support plate. Any of these aspects may include any feature as previously discussed. For example, from central channel 529, each channel 525 may include a radial portion 526 and a vertical portion 527, as described previously with respect to system 300, which may be similar to system 500.

Support plate 520 may define a recessed ledge 530 formed at an exterior location of the support plate as discussed above, and which may be formed to create an amount of overhang of substrate 522 when seated on support plate 520. An edge ring 535 may be seated at an exterior location on the support plate 520 in some embodiments. Edge ring 535 may be located at any location, and may be positioned at a location radially outward of vertical portion 527 of channels 525 to create a flow path about an edge region of substrate 522. Support plate 520 may be coupled with a shaft 545, which may provide access for central channel 529 through the chamber.

In some embodiments, central channel 529 may be fluidly coupled with a pump 550, which may operate opposite any of the purge, dilution, or etch processes as described above. For example, instead of limiting or preventing deposition precursors from accessing the edge region, pump 550 may draw the precursors through channels 525 and out of the system. This may limit residence time of any deposition materials in the edge region, which may further limit or prevent deposition on edge regions and/or a backside of the substrate. Additionally, in some embodiments an additional purge source 555, which may flow any material described previously, may flow a purge fluid through interior flow path 521 beneath an interior region where substrate 522 may be supported. For example, one or more channels may be formed within the substrate support, or any number of protrusions may be included on which the substrate may be seated, or to which the substrate may be electrostatically chucked. The purge source 555 may flow a purge gas through the substrate support and along a backside of the substrate 522. The purge source may flow out the backside of the substrate, and may be pumped through the channels 525 and out of the chamber with deposition materials. This may limit or prevent any deposition materials from accessing a backside of the substrate. An additional benefit of the purge is that the material may further dilute deposition materials, and reduce the likelihood of deposition occurring within channels 525 within the substrate support.

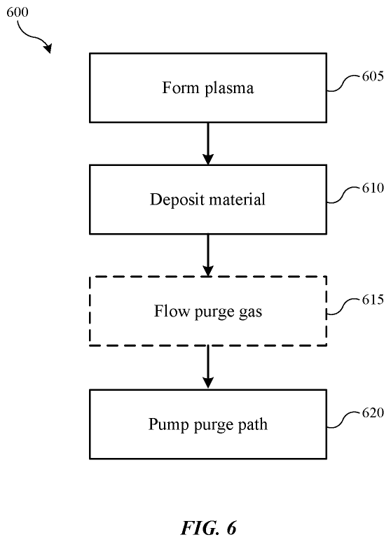

The chamber discussed above may be utilized to perform a purging method. FIG. 6 shows operations of an exemplary method 600 of semiconductor processing according to some embodiments of the present technology. Method 600 may include any of the operations or aspects of method 400 discussed above, and may be performed in any processing chamber previously described, or any other processing chamber in which substrate processing may be performed. For example, as discussed above in method 400, method 600 may include forming a plasma of one or more deposition precursors at operation 605, and depositing material on a substrate at operation 610. The substrate may be seated on a support, such as substrate support 515 described above, and which may be fluidly coupled with a pumping system as discussed for that system.

At optional operation 615, a purge gas may be flowed along a backside of the substrate. A pump may be engaged to purge deposition material and purge gas at operation 620. The purge may include drawing deposition materials, which may be further diluted with purge gas, through channels formed through the support plate of the substrate support as previously described. By performing processes according to embodiments of the present technology, edge and/or backside deposition may be reduced, limited, removed, or prevented. This may improve throughput and may protect substrates from additional etch operations.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a channel” includes a plurality of such channels, and reference to “the fluid” includes reference to one or more fluids and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system, comprising:
a chamber body comprising sidewalls and a base;
a substrate support extending through the base of the chamber body, wherein the substrate support comprises:
a support plate defining a plurality of channels through an interior of the support plate, wherein each channel of the plurality of channels includes a radial portion extending outward from a central channel through the support plate, and a vertical portion formed at an exterior region of the support plate fluidly coupling the radial portion with a support surface of the support plate, and
a shaft coupled with the support plate, wherein the central channel extends through the shaft; and
a fluid source coupled with the central channel of the substrate support.

2. The semiconductor processing system of claim 1, wherein the fluid source comprises a hydrogen-containing precursor or a halogen-containing precursor.

3. The semiconductor processing system of claim 1, further comprising:
a remote plasma source unit coupled with the fluid source, the remote plasma source unit configured to deliver radical species through the central channel of the substrate support.

4. The semiconductor processing system of claim 3, wherein the central channel comprises a corrosion resistant material extending through the shaft of the substrate support.

5. The semiconductor processing system of claim 1, wherein the support plate defines a recessed ledge formed at a radius to create an amount of overhang of a substrate about the support plate.

6. The semiconductor processing system of claim 5, further comprising:
an edge ring seated on an exterior portion of the support plate, wherein the edge ring is positioned radially outward of the vertical portion of each channel of the plurality of channels.

7. The semiconductor processing system of claim 6, wherein the edge ring extends over the vertical portion of each channel to form a fluid path extending over the recessed ledge of the support plate.

8. The semiconductor processing system of claim 6, further comprising:
a shadow ring seated on the edge ring, wherein the shadow ring extends radially inward over a portion of the support plate and forms a fluid path from the plurality of channels defined in the support plate to a substrate support region of the support plate.

9. A semiconductor processing system, comprising:
a chamber body comprising sidewalls and a base;
a substrate support extending through the base of the chamber body, wherein the substrate support comprises:
a support plate defining a plurality of channels through an interior of the support plate, wherein each channel of the plurality of channels includes a radial portion extending outward from a central channel through the support plate, and a vertical portion formed at an exterior region of the support plate fluidly coupling the radial portion with a support surface of the support plate, and wherein the support plate defines a fluid path along a support region of the support plate, and
a shaft coupled with the support plate, wherein the central channel extends through the shaft; and
a fluid pump coupled with the central channel of the substrate support.

10. The semiconductor processing system of claim 9, further comprising:
a purge channel coupled with the fluid path, and configured to deliver a purge gas along the fluid path.

11. The semiconductor processing system of claim 9, wherein the support plate defines a recessed ledge formed at a radius to create an amount of overhang of a substrate about the support plate.

12. The semiconductor processing system of claim 11, further comprising:
an edge ring seated on an exterior portion of the support plate, wherein the edge ring is positioned radially outward of the vertical portion of each channel of the plurality of channels.

13. The semiconductor processing system of claim 12, wherein the edge ring extends over the vertical portion of each channel to form a fluid path extending over the recessed ledge of the support plate.

14. A method of semiconductor processing, comprising:
forming a plasma of a deposition precursor in a processing region of a semiconductor processing chamber;
depositing material on a substrate seated on a substrate support; and
flowing a purge fluid through a plurality of channels formed in the substrate support, wherein the purge fluid limits or removes deposition material from an edge of the substrate.

15. The method of semiconductor processing of claim 14, wherein flowing the purge fluid comprises:
forming plasma effluents of a purge gas, and
flowing the plasma effluents through the plurality of channels formed in the substrate support.

16. The method of semiconductor processing of claim 15, wherein the plasma effluents are flowed subsequent the depositing.

17. The method of semiconductor processing of claim 15, wherein the plasma effluents are flowed during the depositing.

18. The method of semiconductor processing of claim 15, wherein the substrate support comprises:
a support plate defining a plurality of channels through an interior of the support plate, wherein each channel of the plurality of channels includes a radial portion extending outward from a central channel through the support plate, and a vertical portion formed at an exterior region of the support plate fluidly coupling the radial portion with a support surface of the support plate, and
a shaft coupled with the support plate, wherein the central channel extends through the shaft.

19. The method of semiconductor processing of claim 18, wherein the support plate defines a recessed ledge formed at a radius to create an amount of overhang of a substrate about the support plate.

20. The method of semiconductor processing of claim 19, wherein the substrate support further comprises:
an edge ring seated on an exterior portion of the support plate, wherein the edge ring is positioned radially outward of the vertical portion of each channel of the plurality of channels.
